(19) United States
(12) Patent Application Publication
(10) Pub. No.: US 2025/0166967 A1
(43) Pub. Date: May 22, 2025

(54) SYSTEMS AND METHODS FOR REDUCING VARIABILITY IN FEATURES OF A SUBSTRATE

(71) Applicant: Lam Research Corporation, Fremont, CA (US)

(72) Inventors: Sriharsha Jayanti, Fremont, CA (US); Gerardo Delgadino, Milpitas, CA (US); Merrett Wong, San Carlos, CA (US)

(21) Appl. No.: 18/836,734

(22) PCT Filed: Dec. 22, 2022
(86) PCT No.: PCT/US2022/053888

§ 371 Date: Aug. 7, 2024

Related U.S. Application Data
(60) Provisional application No. 63/311,226, filed on Feb. 17, 2022.

(51) Int. Cl. H01J 37/32

(52) U.S. Cl. CPC H01J 37/32146; H01J 37/32183; H01J 2237/334

(57) ABSTRACT

A method for reducing variability between features of a substrate is described. The method includes generating, by a single radio frequency (RF) generator, an RF signal. The method further includes modifying, by the single RF generator, the RF signal to alternate among three states or four states for a time period.

### FIELD

The embodiments described in the present disclosure relate to systems and methods for reducing variability in features of a substrate.

### BACKGROUND

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

One or more radiofrequency (RF) generators generate one or more RF signals and supply the RF signals to a plasma reactor. The plasma reactor has a semiconductor wafer that is etched when the one or more RF signals are supplied and an etchant gas is supplied to the plasma reactor. The semiconductor wafer includes numerous features. When the RF signals are supplied, the features are not etched in a uniform manner.

It is in this context that embodiments described in the present disclosure arise.

### SUMMARY

Embodiments of the disclosure provide systems and methods for reducing variability in features of a substrate. It should be appreciated that the present embodiments can be implemented in numerous ways, e.g., a process, an apparatus, a system, a piece of hardware, or a method on a computer-readable medium. Several embodiments are described below.

As the semiconductor industry scales pitch aggressively and aspect ratios increase, some etch processes suffer from a variety of problems when etching dielectric layers below a patterned hard mask. Issues such as recess loading, profile control, mask shape control, under-etch, and feature-to-feature variation arise. Etching of these dielectric layers is further constrained because addition of bias powers can lead to high mask loss and selectivity tradeoff. Two-state pulsing using a radio frequency (RF) generator can provide control of ion energy and neutral densities over a continuous wave (CW) or process. However, sometimes, the two-state pulsing is insufficient for etching some stacks, with reduced pitches and high aspect ratios in the dielectric layers.

In one embodiment, the methods, described herein, include using three state or four state RF pulsing with a single frequency and a single generator. By using the 3-state pulsed etch, issues of recess loading, profile, and mask shape control are overcome.

The systems and methods, described herein, significantly expand a process window and capabilities to etch dielectric layers, such as the carbon layers, nitride layers, and low-k dielectric layers, below a thin hard mask, where k is a dielectric constant. The systems and methods, described herein, allow additional control of ion energy and neutral or radical flux in etches that cannot withstand high bias or low-frequency. The systems and methods address challenges of recess loading between features, feature to feature CD variation, mask shape control, and under-etching.

In one embodiment, a method for reducing variability between features of a substrate is described. The method includes generating an RF signal that alternates between three or four states for a time period.

In an embodiment, a controller for reducing variability between features of a substrate is described. The controller includes a processor that controls an RF generator to generate an RF signal. The RF signal alternates between three or four states for a time period. The controller includes a memory device coupled to the processor.

In one embodiment, a plasma system is described. The plasma system includes an RF generator that generates an RF signal. The plasma system further includes a match coupled to the RF generator and a plasma chamber coupled to the match. The plasma system includes a controller coupled to the RF generator. The controller controls the RF generator to generate the RF signal. The RF signal alternates between three states for a time period.

Some advantages of the herein described systems and methods include reducing variability in features of a first substrate. By applying a set of three states to the first substrate, the variability is reduced. Also, a variability in bars is reduced. Each bar is a distance between two consecutive features.

Additional advantages of the herein described systems and methods include continuing to reduce the variability in case a second substrate that has a greater depth than the first substrate is used. By applying a set of four states following the set of three states to the second substrate, the variability is reduced.

In one embodiment, instead of applying the set of four states following the set of three states, the set of four states is applied at all times to reduce variability in the features. For example, the set of four states is applied instead of the set of three states when a mask opening CD of the patterned hard mask decreases. When the mask opening CD decreases, an aspect ratio of the features increases.

It should be noted that a number of states applied depend on one of more of a variety of factors, such as, a depth of the substrate, aspect ratio of the features, mask CDs, mask shape, and mask hardness. For example, a softer mask is more prone to deformation, in which case one or two states are applied to etch and shape the mask opening.

Some other aspects will become apparent from the following detailed description, taken in conjunction with the accompanying drawings.

### BRIEF DESCRIPTION OF THE DRAWINGS

The embodiments are understood by reference to the following description taken in conjunction with the accompanying drawings. It should be noted that some of the drawings are not to scale.

FIG. 1 is a diagram of an embodiment of a system to illustrate a radio frequency (RF) generator for processing a substrate.

FIG. 2A is an embodiment of a graph to illustrate multiple sets of states of an RF signal generated by the RF generator of FIG. 1.

FIG. 2B is an embodiment of a graph to illustrate a clock signal having multiple cycles.

FIG. 3A is a side view of an embodiment of a substrate.

FIG. 3B is a side view of an embodiment of a substrate, which is the same as the substrate of FIG. 3A after being processed.

FIG. 3C is a top view of an embodiment of a dielectric layer of the substrate of FIG. 3B.

FIG. 4 is a diagram of an embodiment of a system for illustrating generation of multiple states of an RF signal generated by the RF generator of FIG. 1.

FIG. 5 is an embodiment of a graph to illustrate multiple sets of states of an RF signal.

FIG. 6 is a diagram of an embodiment of a system for illustrating generation of multiple states of an RF signal generated by the RF generator of FIG. 1.

### DETAILED DESCRIPTION

The following embodiments describe systems and methods for reducing variability in features of a substrate. It will be apparent that the present embodiments may be practiced without some or all of these specific details. In other instances, well known process operations have not been described in detail in order not to unnecessarily obscure the present embodiments.

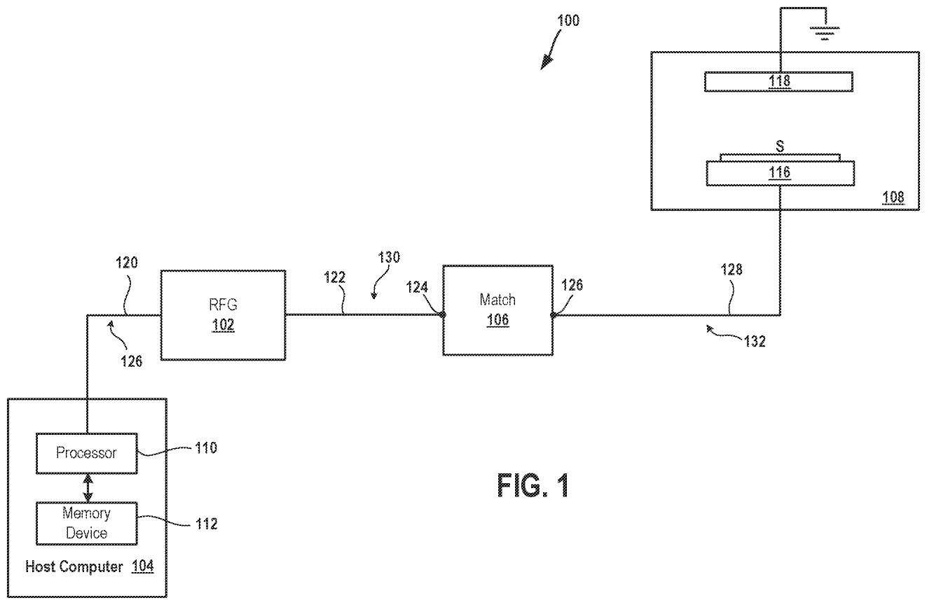

FIG. 1 is a diagram of an embodiment of a system 100 to illustrate a radio frequency (RF) generator 102 for processing a substrate S. The system 100 includes the RF generator 102, a host computer 104, a match 106, and a plasma chamber 108. The host computer 104 includes a processor 110 and a memory device 112. The plasma chamber 108 includes a chuck 116, such as an electrostatic chuck (ESC), and an upper electrode 118. An example of the plasma chamber 108 is a capacitively coupled plasma (CCP) chamber.

An example of a host computer is a desktop computer, a laptop computer, a smartphone, and a tablet. An example of the RF generator 102 is a high frequency (HF) RF generator having a high frequency of operation, such as, a fundamental frequency of 60 megahertz (MHz). To illustrate, the RF generator 102 is not a low frequency (LF) RF generator, such as a 400 kilohertz (kHz) RF generator or a 2 MHz RF generator, or is not a medium frequency RF generator, such as a 27 MHz RF generator. As another illustration, when the RF generator 102 operates at the high frequency of operation, frequencies of an RF signal 130 generated by the RF generator 102 range from 57 MHz to 63 MHz.

As an example, the RF generator 102 is a single RF generator. To illustrate, there is no other RF generator coupled to the match 106 via an RF cable. In the illustration, only the RF generator 102 is coupled to the match 106.

The high frequency of operation of the HF RF generator is sometimes referred to herein as a single frequency. Also, the RF generator 102 is sometimes referred to herein as a single RF generator. For example, there is no other RF generator used in the system 100 except for the RF generator 102 in a time period in which the RF generator 102 is powered on to supply the RF signal 130. As another, any other RF generator, if used in the system 100, is powered off during the time period the RF generator 102 is powered on to supply the RF signal 130. When the other RF generator is powered off, the other RF generator does not generate an RF signal.

It is difficult to etch a mask layer, such as a thin mask layer, of the substrate S using any of the low and medium frequency RF generators. The low and medium frequency generators generate a high amount of power, which creates a high amount of ion energy of plasma ions within the plasma chamber 108. The high amount of ion energy is not suitable to etch the mask layer. For example, the mask layer cannot be etched by the high amount of ion energy.

Examples of a processor include a central processing unit (CPU), a microprocessor, an application specific integrated circuit (ASIC), and a programmable logic device (PLD). Examples of a memory device include a random access memory (RAM) and a read-only memory (ROM).

An example of the match 106 includes a network of circuit components. For example, the match 106 includes a first branch circuit between an input 124 of the match 106 and an output 126 of the match 106. A branch circuit includes one or more of the circuit components, such as resistors, capacitors, and inductors. For example, the branch circuit includes one or more series circuits and one or more shunt circuits. In the example, each of the series circuits includes one or more of the circuit components and each of the shunt circuits includes one or more of the circuit components.

The chuck 116 includes a lower electrode, which is fabricated from aluminum or an alloy of aluminum. Similarly, the upper electrode 118 is fabricated from aluminum or the alloy of aluminum. The upper electrode 118 faces the chuck 116 and the substrate S is placed on a top surface of the chuck 116 for processing. Examples of the substrate S include a semiconductor wafer on which integrated circuits are fabricated.

The processor 110 is coupled to the memory device 112. Also, the processor 110 is coupled via a transfer cable 120 to the RF generator 102. As an example, a transfer cable transfers a signal using a parallel transfer protocol, a serial transfer protocol, or a universal serial bus (USB) protocol. The RF generator 102 is coupled via an RF cable 122 to the input 124 of the match 106. The output 126 of the match 106 is coupled via an RF transmission line 128 to the chuck 116.

The processor 110 generates and sends a recipe signal 126 via the transfer cable 120 to the RF generator 102. The recipe signal 126 includes the frequency of operation of the RF generator 102, multiple sets of multiple states of the RF signal 130 to be generated by the RF generator 102, duty cycles of the states, and time periods for which the sets of multiple states are to occur. An example of a state of an RF signal is a power level of the RF signal. To illustrate, the state is an envelope of an amplitude of the RF signal. To further illustrate, the state is a peak-to-peak amplitude or a zero-to-peak amplitude of the RF signal. After receiving the recipe signal 126, the RF generator 102 generates the RF signal 130 having the sets of states according to the time periods of the sets, and the duty cycles of the states. The RF generator 102 sends the RF signal 130 via the RF cable 122 to the input 124 of the match 106.

The match 106 receives the RF signal 130 at the input 124 and matches an impedance of a load coupled to the output 126 with an impedance of a source coupled to the input 124 to modify an impedance of the RF signal 130 to output a modified RF signal 132 at the output 126. An example of the source coupled to the input 124 includes the RF cable 122 and the RF generator 102. An example of the load includes the RF transmission line 128 and the plasma chamber 108. The modified RF signal 132 is sent from the output 126 via the RF transmission line 128 to the lower electrode of the chuck 116.

When one or more process gases, such as a nitrogen-containing gas, a fluorine-containing gas, and an oxygen-containing gas, are supplied to a gap between the chuck 116 and the upper electrode 118 and when the lower electrode receives the modified RF signal 132, plasma is stricken or maintained within the gap to process the substrate S. Example of processing the substrate S include depositing one or more materials on the substrate S, etching the substrate S to fabricate features of the substrate S, and cleaning the substrate S.

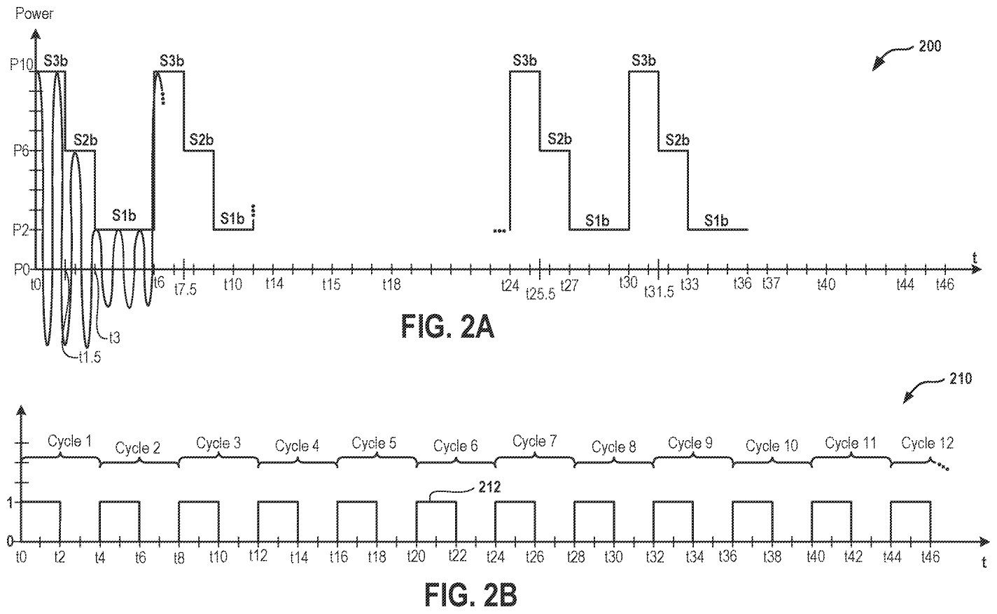

FIG. 2A is an embodiment of a graph 200 to illustrate the multiple sets of the states of an RF signal 202. The RF signal 202 is an example of the RF signal 130 (FIG. 1). The graph 200 plots power levels of an RF signal 202 versus time t. The power levels are plotted on a y-axis and the time t is plotted on an x-axis. On the y-axis of the graph 200, the power levels range from a power level P0 to a power level P10. An example of the power level P0 is zero. As an example, the power level P2 ranges from 0 watts (W) to 500 W. To illustrate, the power level P2 is 200 W. Further, as an example, the power level P6 ranges from 100 W to 1500 W. For instance, the power level P6 is 500 W. Also, as an example, the power level P10 ranges from 500 W to 5000 W. To illustrate, the power level P10 is 1000 W. The power levels increase in a positive y direction of the y-axis of the graph 200. For example, the power levels increase from P0 to P10. On the x-axis of the graph 200, the time t increases from a time t0 to a time t46.

The RF signal 202 alternates, such as transitions periodically, among three states S3b, S2b, and S1b in a step-down manner during a time period between the times t0 and t36. For example, during a cycle 1 of a clock signal 212 (FIG. 2B), the RF signal 202 transitions at the time t0 from a power level of zero to the power level P10 and maintains the power level P10 from the time t0 to the time t1.5. During the cycle 1 of the clock signal 212, the RF signal 202 transitions at the time t1.5 from the power level P10 to the power level P6 and remains at the power level P6 from the time t1.5 to the time t3.

During a cycle 2 of the clock signal 212, the RF signal 202 transitions, at the time t3, from the power level P6 to the power level P2, and remains at the power level P2 from the time t3 to the time t6. The power level P10 is a state S3b of the RF signal 202, the power level P6 is a state S2b of the RF signal 202, and the power level P2 is a state S1b of the RF signal 202. Also, a time interval between the times t0 and t1.5 is an example of a duty cycle of the state S3b, a time interval between the times t1.5 and t3 is an example of a duty cycle of the state S2b, and a time interval between the times t3 and t6 is an example of a duty cycle of the state S1b. As an example, a duty cycle of the state S3b ranges from 1% to 30%, a duty cycle of the state S2b ranges from 5% to 60%, and a duty cycle of the state S1b is a difference between 100% and a sum of the duty cycles of the states S3b and S2b. To illustrate, the duty cycle of the state S1b ranges from 10% to 94%. The states S1b, S2b, and S3b form a set of states of the RF signal 202.

During a cycle 3, a cycle 4, a cycle 5, and a cycle 6 of the clock signal 212, the RF signal 202 repeats the transitions among the three states S3b, S2b, and S1b in the same manner as that from the time t0 to the time t6. For example, the RF signal 202 transitions again among the power levels P10, P6, and P2 from the time t6 to the time t24 in the same manner in which the RF signal 202 transitions among the power levels P10, P6 and P2 from the time t0 to the time t6. The RF signal 202 continues to alternate, such as transitions periodically, among the states S3b, S2b and S1b, during the time period between the times t24 and t36 in the step-down manner.

It should be noted that the three states S3b, S2b, and S1b during the time period between the times t0 and t24 etch a mask layer of the substrate S and a first portion of a dielectric layer, such as a carbon-based layer or a low dielectric constant layer, of the substrate S. An example of the first portion of the dielectric layer is a range between 5% and 80% of the dielectric layer. To illustrate, the first portion of the dielectric layer is 50% of the dielectric layer. The dielectric layer is located immediately below the mask layer. Moreover, the states S3b, S2b, and S1b during the time period between the times t24 and t36 etch a remaining portion of the dielectric layer. An example of the remaining portion of the dielectric layer is a range between 20% and 60% of the dielectric layer. To illustrate, the remaining portion of the dielectric layer is 50% of the dielectric layer. The time period between the times t0 and t36 is sometimes referred to herein as a first time period.

In one embodiment, the three states S3b, S2b, and S1b repeat for a first number of times, such as four times or five times or six times, during the time period between the times t0 and t36.

In an embodiment, a first power level, such as P10, of an RF signal has power values, such as peak-to-peak values or zero-to-peak values, of power of the RF signal that are within a preset range from each other. Also, a second power level, such as P6, of the RF signal has power values, such as peak-to-peak values or zero-to-peak values, of power of the RF signal that are within a preset range from each other. All the power values of the first power level are exclusive of the power values of the second power level. For example, there is at least a 10% difference between a maximum power value of the second power level and a minimum power value of the first power level. In the example, the second power level is lower than the first power level. Another example of the first power level is P6 and the second power level is P2.

In an embodiment, the state S2b is a power level between the power levels P6 and P10.

In one embodiment, the state S1b is a power level between the power levels P2 and P6 or between the power levels P0 and P2.

In an embodiment, the state S3b is a power level that is greater than the power level P10, such as a power level P11 or a power level P12. The power level P12 is greater than the power level P11, which is greater than the power level P10.

In one embodiment, at least one state, such as a continuous wave (CW), of the RF signal 130 etches the mask layer of the substrate S or both the mask layer and the first portion of the dielectric layer. In the embodiment, the three states S3b, S2b, and S1b etch the remaining portion of the dielectric layer.

FIG. 2B is an embodiment of a graph 210 to illustrate the clock signal 212 having the cycle 1, the cycle 2, and so on until a cycle 11. The graph 210 plots a logic level, such as a voltage, of the clock signal 212 on a y-axis and the time t on an x-axis. The y-axis of the graph 210 has logic levels ranging from 0 to 1. The logic level 1 is greater than the logic level 0. The processor 110 (FIG. 1) generates the clock signal 212 and sends the clock signal 212 via the transfer cable 120 (FIG. 1) to the RF generator 102 (FIG. 1) to synchronize repetition of each set of states with a transition of the clock signal 212. For example, the states S3b, S2b, and S1b repeat at the time t6 for a second time during the time period between the times t6 and t12. As another example, the states S3b, S2b, and S1b repeat for a third time at the time t12 for a third time during the time period between the times t12 and t18.

During the cycle 1, the clock signal 212 transitions from the logic level 0 to the logic level 1 at the time t0 and maintains the logic level 1 from the time t0 to the time t2. Also, during the cycle 1, the clock signal 212 transitions from the logic level 1 to the logic level 0 at the time t2 and maintains the logic level 0 from the time t2 to the time t4. The logic levels 1 and 0 repeat in the same manner during each of the cycles 2 through 11 in the same manner as that during the cycle 1.

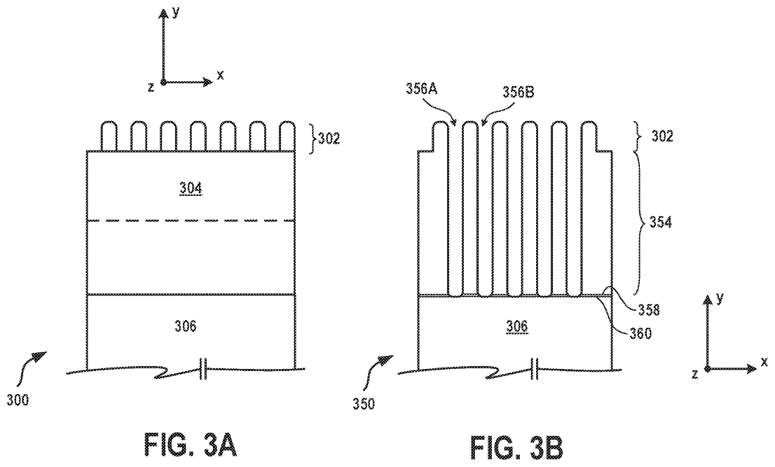

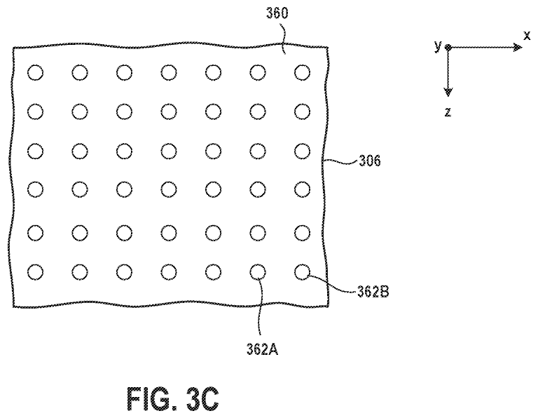

FIG. 3A is a side view of an embodiment of a substrate 300, which is an example of the substrate S. The substrate 300 includes a mask layer 302, a dielectric layer 304, and a dielectric layer 306. The dielectric layer 304 is located immediately below the mask layer 302 and the dielectric layer 306 is located immediately below the dielectric layer 304.

An example of the mask layer 302 is a layer fabricated from a combination of silicon and carbon or a combination of silicon oxide and carbon. Another example of the mask layer 302 is a layer including a photoresist, or silicon, or silicon dioxide (SiO2), or silicon nitride (SiN), or silicon oxynitride (SiON), or titanium nitride (TiN), or titanium oxide (TiO), or a combination of two or more thereof. As an example, the mask layer 302 has a height ranging from 90 nanometers (nm) to 130 nm. To illustrate, the mask layer 302 has a height of 110 nm.

The mask layer 302 includes multiple mask sub-layers, such as a first mask sub-layer and a second mask sub-layer. As an example, the first mask sub-layer has a different orientation of patterns compared to an orientation of patterns of the second mask sub-layer. For example, the patterns of the second mask sub-layer are angled with respect to the patterns of the first mask sub-layer.

An example of the dielectric layer 304 is one that includes a combination of carbon, hydrogen, oxygen, and nitrogen. As another example, the dielectric layer 304 is a carbon-based layer that includes carbon and one or more of hydrogen, oxygen, and nitrogen. As yet another example, the dielectric layer 304 is fabricated from silicon, or SiON, or is a silicon-doped layer. As yet another example, the dielectric layer 304 is a low-k dielectric layer, such as a SiN layer or another nitride layer, where k is a dielectric constant. As an example, the dielectric layer 304 has a height ranging from 150 nm to 250 nm. To illustrate, the dielectric layer 304 has a height of 200 nm.

An example of the dielectric layer 306 is an oxide-based layer. Another example of the dielectric layer 306 is a layer fabricated from silicon, or a layer fabricated from SiN, or a layer fabricated from SiON, or a silicon-doped layer.

A height of a layer is measured in a vertical direction along a y-axis. A breadth of the layer is measured along a z-axis, and a width of the layer is measured along an x-axis. The x-axis is perpendicular to the y-axis, which is perpendicular to the z-axis. Also, the x-axis is perpendicular to the z-axis. The height of the layer is sometimes referred to herein as a depth of the layer.

The states S3b, S2b, and S1b (FIG. 2A) of the RF signal 202 etch the mask layer 302 and the first portion of the dielectric layer 304 during the time period between the times t0 and t24. Moreover, the states S3b, S2b, and S1b of the RF signal 202 etch the remaining portion of the dielectric layer 304 during the time period between the times t24 and t36. The remaining portion of the dielectric layer 304 extends from the first portion of the dielectric layer 304 to the dielectric layer 306, and the first portion of the dielectric layer 304 extends from the mask layer 302 to the remaining portion of the dielectric layer 304. The first portion of the dielectric layer 304 is located below and adjacent to the mask layer 302, and the remaining portion of the dielectric layer 304 is located below and adjacent to the first portion of the dielectric layer 304. The dielectric layer 306 is located below the dielectric layer 304. The dielectric layer 306 is etched by a modified RF signal that is generated by a combination of the RF signal 130 and an LF RF signal generated by the LF RF generator.

The LF RF generator, when used, is coupled to an additional input of the match 106 via an additional RF cable. The LF RF generator generates and sends the LF RF signal to the additional input of the match 106. The match 106 further includes a second branch circuit that is coupled between the additional input and the output 126. The second branch circuit is coupled to the additional input and the output 126. The second branch circuit includes one or more of the circuit components. The second branch circuit receives the LF RF signal and matches an impedance of the load with that of a source coupled to the additional input to modify an impedance of the LF RF signal to output an additional modified RF signal. An example of the source coupled to the additional input includes the additional RF cable and the LF RF generator. The modified RF signal 132 (FIG. 1) and the additional modified RF signal are combined, such as summed or added, at the output 126 of the match 106 to output a combined modified RF signal. The combined modified RF signal is sent from the output 126 of the match 106 via the RF transmission line 128 to the lower electrode of the chuck 116 (FIG. 1) for processing the substrate S.

It should be noted that during the first time period in which the mask layer 302 and the dielectric layer 304 are etched, the LF RF generator is turned off. For example, the processor 110 sends a recipe signal to the LF RF generator indicating a power level of zero during the first time period. Upon receiving the recipe signal, the LF RF generator does not generate the LF RF signal and does not supply the LF RF signal to the match 106. At the time the dielectric layer 306 is to be etched, the LF RF generator is turned on to generate the LF RF signal having a positive power level. As another example, during the first time period in which the LF RF generator is turned off, the single RF generator 102 is used.

FIG. 3B is a side view of an embodiment of a substrate 350, which is the same as the substrate 300 after being processed. The substrate 350 includes the mask layer 302 and a dielectric layer 354. The mask layer 302 has features, such as trenches, etched into the mask layer 302. Some of the features are shown as a feature 356A and a feature 356B. Moreover, the dielectric layer 354 is the same as the dielectric layer 304 except that the dielectric layer 354 has the features etched in the dielectric layer 304. The features are created by the RF signal 130 (FIG. 1). The dielectric layer 354 has a bottom surface 358, which is adjacent to a top surface 360 of the dielectric layer 306.

In an embodiment, each substrate 300 and 350 excludes the mask layer 302.

In one embodiment, the substrate 300 includes a mask layer that is not etched to have the features.

FIG. 3C is a top view of an embodiment of the dielectric layer 306 having the features. For example, the top surface 360 of the dielectric layer 306 has a feature 362A and a feature 362B formed therein. It should be noted that each feature extends through the mask layer 302 (FIG. 3A) and the dielectric layer 304 (FIG. 3A) and extends slightly into a top surface of the dielectric layer 306. The features of the top view of the dielectric layer 306 also represent a top view of the bottom surface 358 (FIG. 3B) of the dielectric layer 354 (FIG. 3B),

There is a decrease in variability in a critical dimension (CD) from feature to feature due to the supply of the RF signal 130 (FIG. 1). For example, a diameter of the feature 362A is within a pre-determined range from a diameter of the feature 362B. Also, a variability in a bar, which is distance, between any two consecutive features, is reduced due to the supply of the RF signal 130.

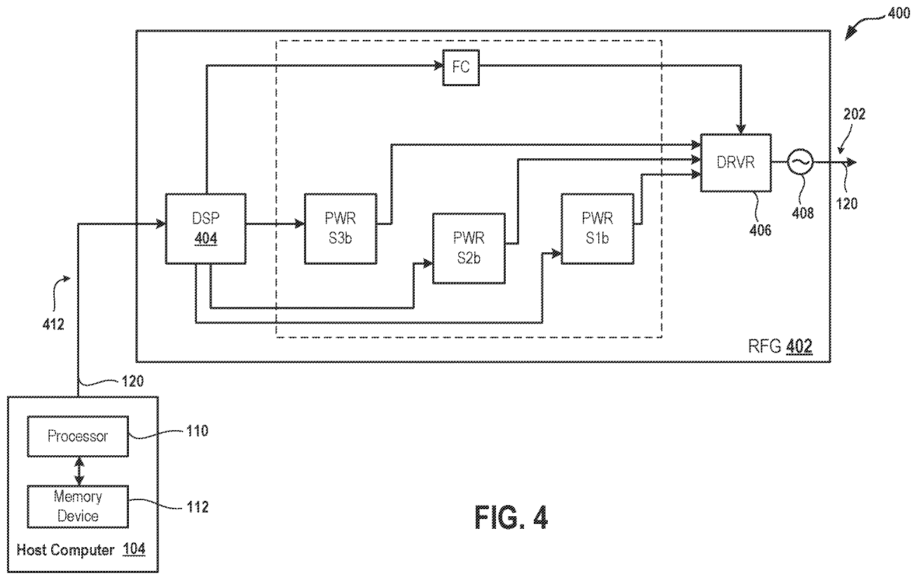

FIG. 4 is a diagram of an embodiment of a system 400 for illustrating generation of the states S3b, S2b, and S1b. The system 400 includes an RF generator 402 and the host computer 104. The RF generator 402 is an example of the RF generator 102 (FIG. 1).

The RF generator 402 includes a digital signal processor (DSP) 404, a power controller PWRS3b, a power controller PWRS2b, a power controller PWRS1b, and a frequency controller FC. The power controllers PWRS3b, PWRS2b, and PWRS1b are components of a controller system 403. The RF generator 402 further includes a driver system (DRVR) 406 and an RF power supply 408.

An example of a controller includes a processor and a memory device. The processor of the controller is coupled to the memory device of the controller. For example, the controller is a microcontroller. An example of a driver system is a circuit that includes one or more transistors. The transistors are coupled to each other. An example of an RF power supply is an electronic oscillator that produces the RF signal 130 having a radio frequency.

The processor 110 is coupled via the transfer cable 120 to the DSP 404. The DSP 404 is coupled to the power controllers PWRS3b, PWRS2b, and PWRS1b. The power controllers PWRS3b, PWRS2b, and PWRS1b and the frequency controller FC are coupled to the driver system 406, and the driver system 406 is coupled to the RF power supply 408. The RF power supply 408 is coupled to the RF cable 120 (FIG. 1).

The processor 110 generates and sends a recipe signal 412 via the transfer cable 120 to the DSP 404. The recipe signal 412 is an example of the recipe signal 126 (FIG. 1). The recipe signal 412 includes information regarding the RF signal 202 (FIG. 2A), such as the frequency of operation of the RF generator 402, a set of the states S3b, S2b, and S1b of the RF signal 202, and duty cycles of the states S3b, S2b, and S1b. The information regarding the RF signal 202 further includes the first time period, such as the time period between the times t0 and t36, for which one or more instances, such as occurrences, of the states S3b, S2b, and S1b are to occur. The information regarding the RF signal 202 also includes an indication to initiate pulsing the RF signal 202 among the states S3b, S2b, and S1b. The DSP 404 stores the duty cycles of the states S3b, S2b, and S1b, the first time period, and the indication to initiate pulsing of the RF signal 202 among the states S3b, S2b, and S1b within a memory device of the DSP.

Upon receiving the recipe signal 412, the DSP 404 identifies the states S3b, S2b, and S1b and the duty cycles for the states S3b, S2b, and S1b from the recipe signal 412, and provides the states S3b, S2b, and S1b and the duty cycles to the power controllers PWRS3b, PWRS2b, and PWRS1b. For example, the state S3b and the duty cycle of the state S3b is sent to the power controller PWRS3b, the state S2b and the duty cycle of the state S2b is sent to the power controller PWRS2b, and the state S1b and the duty cycle of the state S1b is sent to the power controller PWRS1b.

Each power controller PWRS3b, PWRS2b, and PWRS1b stores a respective one of the states S3b, S2b, and S1b and a respective one of the duty cycles of the states S3b, S2b, and S1b. For example, the processor of the power controller PWRS3b stores the state S3b and the duty cycle for which the state S3b is to occur in the memory device of the power controller PWRS3b, the power controller PWRS2b stores the state S2b and the duty cycle for which the state S2b is to occur in the memory device of the power controller PWRS2b, and the power controller PWRS1b stores the state S1b and the duty cycle for which the state S1b is to occur in the memory device of the power controller PWRS1b.

Also, the DSP 404 identifies the frequency of operation of the RF generator 402 from the recipe signal 412 and provides the frequency of operation to the frequency controller FC. The processor of the frequency controller FC stores the frequency of operation within the memory device of the frequency controller FC.

Moreover, the DSP 404 receives the clock signal 212 from the processor 110 via the transfer cable 120. After receiving the clock signal 212, the DSP 404 sends a frequency control signal to the frequency controller FC and sends a power control signal to the power controller PWRS3b to provide the state S3b for the duty cycle of the state S3b. Upon receiving the power control signal, the power controller PWRS3b sends the state S3b to the driver system 406. The driver system 406 generates a drive signal upon receiving the state S3b and the frequency of operation based on the power level of the state S3b and the frequency of operation, and sends the drive signal to the RF power supply 408. The RF power supply 408 generates the RF signal 202 having the state S3b for the duty cycle of the state S3b and having the frequency of operation upon receiving the drive signal from the driver system 406.

The power controller PWRS3b determines that the time interval for the duty cycle of the state S3b has ended and stops sending the state S3b to the driver system 406 at the end of the duty cycle of the state S3b. When the driver system 406 does not receive the state S3b, the driver system 406 stops generating the drive signal based on the state S3b. Upon not receiving the drive signal based on the state S3b, the RF power supply 408 does not generate the state S3b of the RF signal 202.

Moreover, at the end of the time interval for the duty cycle of the state S3b, the DSP 404 sends a power control signal to the power controller PWRS2b to provide the state S2b for the duty cycle of the state S2b. Upon receiving the power control signal, the power controller PWRS2b sends the state S2b to the driver system 406. The driver system 406 generates a drive signal upon receiving the state S2b and the frequency of operation based on the power level of the state S2b and the frequency of operation, and sends the drive signal to the RF power supply 408. The RF power supply 408 generates the RF signal 202 having the state S2b for the duty cycle of the state S2b and having the frequency of operation upon receiving the drive signal from the driver system 406.

The power controller PWRS2b determines that the time interval for the duty cycle of the state S2b has ended and stops sending the state S2b to the driver system 406 at the end of the duty cycle of the state S2b. When the driver system 406 does not receive the state S2b, the driver system 406 stops generating the drive signal based on the state S2b. Upon not receiving the drive signal based on the state S2b, the RF power supply 408 does not generate the state S2b of the RF signal 202.

Furthermore, at the end of the time interval for the duty cycle of the state S2b, the DSP 404 sends a power control signal to the power controller PWRS1b to provide the state S1b for the duty cycle of the state S1b. Upon receiving the power control signal, the power controller PWRS1b sends the state S1b to the driver system 406. The driver system 406 generates a drive signal upon receiving the state S1b and the frequency of operation based on the power level of the state S1b and the frequency of operation, and sends the drive signal to the RF power supply 408. The RF power supply 408 generates the RF signal 202 having the state S1b for the duty cycle of the state S1b and having the frequency of operation upon receiving the drive signal from the driver system 406.

The power controller PWRS1b determines that the time interval for the duty cycle of the state S1b has ended and stops sending the state S1b to the driver system 406 at the end of the duty cycle of the state S1b. When the driver system 406 does not receive the state S1b, the driver system 406 stops generating the drive signal based on the state S1b. Upon not receiving the drive signal based on the state S1b, the RF power supply 408 does not generate the state S1b of the RF signal 202. In this manner, the DSP 404 controls the power controllers PWRS3b, PWRS2b, and PWRS1b, and the frequency controller FC to generate the RF signal 202 having the states S3b, S2b, and S1b and the frequency of operation for the first time period.

It should be noted that when a new recipe signal indicating a change in power level for a state is received by the DSP 404 from the processor 110 via the transfer cable 120, a change in the power level for the state occurs. For example, the processor 110 sends a recipe signal including a power level that is greater than the power level of the state S3b and a duty cycle of the greater power level to the DSP 404. Upon receiving the greater power level and the duty cycle, the DSP 404 controls the power controller PWRS3b to further control the RF power supply 408 to increase the power level for the state S3b to the greater power level for a time period of the duty cycle. The power controller PSRS3b is controlled in the same manner to achieve the greater power level for the duty cycle in the same manner in which the power controller PSRS3b is controlled to achieve the power level of the state S3b.

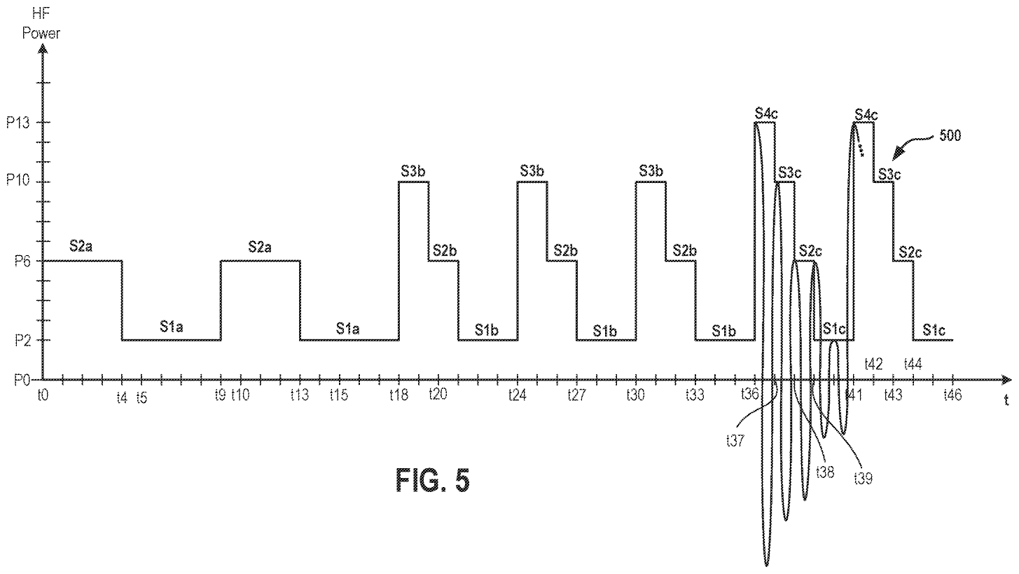

FIG. 5 is an embodiment of a graph 500 to illustrate the multiple sets of the states of an RF signal 502. The RF signal 502 is an example of the RF signal 130 (FIG. 1). The graph 500 plots power levels of the RF signal 502 versus the time t. The power levels are plotted on a y-axis and the time t is plotted on an x-axis. On the y-axis of the graph 500, power levels range from the power level P0 to a power level P13. The power levels increase in the positive y direction of the y-axis of the graph 500. For example, the power levels increase from P0 to P13. On the x-axis of the graph 500, the time t increases from the time t0 to a time t42.

The RF signal 502 transitions periodically between a set of states S2a and S1a from the time t0 to the time t18. The state S2a is the power level P6 and the state S1a is the power level P2. At the time t18, the RF signal 502 transitions among the states S3b, S2b, and S1b until the time t36. Thereafter, starting at the time t36, the RF signal 502 alternates, such as transitions periodically, among a set of four states S4c, S3c, S2c, and S1c. The RF signal 502 transitions among the states S4c through S1c during the time period between the times t36 and t46 in a step-down manner. For example, during the cycle 10 of the clock signal 212 (FIG. 2B), the RF signal 502 transitions at the time t36 from the power level P2 to the power level P13 and maintains the power level P13 from the time t36 to the time t37. Also, the RF signal 502 transitions at the time t37 from the power level P13 to the power level P10 and remains at the power level P10 from the time t37 to the time t38. Moreover, the RF signal 502 transitions at the time t38 from the power level P10 to the power level P6 and remains at the power level P6 from the time t38 to the time t39. The RF signal 502 transitions at the time t39 from the power level P6 to the power level P2 and remains at the power level P2 from the time t39 to the time t41.

During the cycles 11 and 12 of the clock signal 212, the RF signal 502 repeats the transitions between the power levels P13, P10, P6, and P2 in the same manner as that during the cycles 10 and 11. For example, the power levels P13, P10, P6, and P2 repeat from the time t41 to the time t46 in the same manner as that of the occurrence of the power levels P13, P10, P6, and P2 from the time t36 to the time t41.

The power level P13 is a state S4c of the RF signal 502, the power level P10 is a state S3c of the RF signal 502, the power level P6 is a state S2c of the RF signal 502, and the power level P2 is a state S1c of the RF signal 502. Also, a time interval between the times t36 and t37 is an example of a duty cycle of the state S4c, a time interval between the times t37 and t38 is an example of a duty cycle of the state S3c, a time interval between the times t38 and t39 is an example of a duty cycle of the state S2c, and a time interval between the times t39 and t41 is an example of a duty cycle of the state S1c. The states S4c, S3c, S2c, and S1c form a set of states of the RF signal 502. Also, the state S4c through S1c occur for a second time period. The second time period is from the time t36 to the time t46.

It should be noted that the states S4c, S3c, S2c, and S1c etch a dielectric layer of a substrate (not shown) that is deeper than the dielectric layer 304 (FIG. 3A). For example, the states S3b, S2b, and S1b etch a mask layer of the substrate (not shown) and one or more portions of a dielectric layer of the substrate (not shown). The states S4c, S3c, S2c, and S1c etch the remaining portion of the dielectric layer. The dielectric layer is located below the mask layer. Also, the remaining portion of the dielectric layer is located below the one or more portions of the dielectric layer.

In an embodiment, three states are used to etch the substrate having the dielectric layer that is deeper than the dielectric layer 304. For instance, in the preceding example, instead of using the states S4c, S3c, S2c, and S1c to etch the remaining portion of the dielectric layer, a high power level state is used instead of the power level of the state S3b. The high power level is greater than the power level of the state S3b.

In one embodiment, the states S4c, S3c, S2c, and S1c repeat for a second number of times. For example, instead of repeating twice during the time period between the times t36 and t46 as illustrated in FIG. 5, the states S4c, S3c, S2c, and S1c occur once or repeat thrice. As an example, the second number is equal to the first number for which the states S3b, S2b, and S1b occur. As another example, the second number is different from the first number of times.

In an embodiment, the state S3c has a different power level than that of the state S3b. For example, the state S3c is a power level between the power levels P10 and P13 or greater than the power level P13.

In an embodiment, the state S2c has a different power level than that of the state S2b. For example, the state S2c is a power level between the power levels P6 and P10.

In one embodiment, the state S1c has a different power level than that of the state S1b. For example, the state S1c is a power level between the power levels P2 and P6 or between the power levels P0 and P2.

In an embodiment, the states S3b, S2b, S1b, S4c, S3c, S2c, and S1c, duty cycles for the states S3b, S2b, S1b, S4c, S3c, S2c, and S1c, the first time period for occurrences of the states S3b, S2b, and S1b, and the second time period for occurrences of the states S4c, S3c, S2c, and S1c are empirically determined by the processor 110 during an experimental process. The states S3b, S2b, S1b, S4c, S3c, S2c, and S1c are stored in the memory device 112 by the processor 110 for access during processing of the substrate S.

In one embodiment, the states S4c, S3c, S2c, and S1c occur at the time t0 instead of the states S3b, S2b, and S1b. The states S4c through S1c occur for a number of times, such as for example, from the time t0 to the time t46.

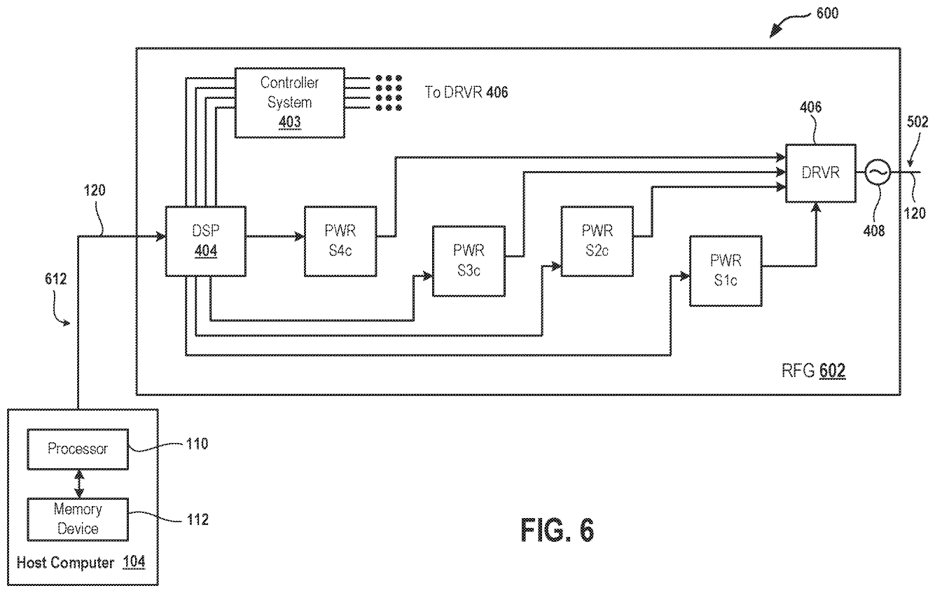

FIG. 6 is a diagram of an embodiment of a system 600 for illustrating generation of the states S4c, S3c, S2c, and S1c. The system 600 includes an RF generator 602 and the host computer 104. The RF generator 602 is an example of the RF generator 102 (FIG. 1).

The RF generator 602 includes the DSP 404, the controller system 403, a power controller PWRS4c, a power controller PWRS3c, a power controller PWRS2c, and a power controller PWRS1c. The RF generator 602 further includes the driver system 406, and the RF power supply 408.

The DSP 404 is coupled to the power controllers PWRS4c, PWRS3c, PWRS2c, and PWRS1c. The power controllers PWRS4c, PWRS3c, PWRS2c, and PWRS1c are coupled to the driver system 406.

The processor 110 generates and sends a recipe signal 612 via the transfer cable 120 to the DSP 404. The recipe signal 612 is an example of the recipe signal 126 (FIG. 1). The recipe signal 612 includes the frequency of operation of the RF generator 602, the set of the states S3b, S2b, and S1b of the RF signal 502, a set of the states S4c, S3c, S2c, and S1c of the RF signal 502, and the duty cycles of the states S3b, S2b, S1b, S4c, S3c, S2c, and S1c. The recipe signal 612 further includes the first time period for which the set of states S3b through S1b are to occur and the second time period for which the states S4c, S3c, S2c, and S1c are to occur. The recipe signal 612 further includes the indication to initiate pulsing the RF signal 502 among the states S3b, S2b, and S1b. The DSP 404 stores, within the memory device of the DSP 404, the duty cycles of the states S4c, S3c, S2c, and S1c, the second time period, and the indication to initiate pulsing of the RF signal 502 among the states S3b, S2b, and S1b.

Upon receiving the recipe signal 612, the DSP 404 identifies, from the recipe signal 612, the states S4c, S3c, S2c, and S1c and the duty cycles for which the states S4c, S3c, S2c, and S1c are to occur, and provides the states S4c, S3c, S2c, and S1c and the duty cycles for the states S4c, S3c, S2c, and S1c to the power controllers PWRS4c, PWRS3c, PWRS2c, and PWRS1c. For example, the state S4c and the duty cycle of the state S4c is sent to the power controller PWRS4c, the state S3c and the duty cycle of the state S3c is sent to the power controller PWRS3c, the state S2c and the duty cycle of the state S2c is sent to the power controller PWRS2c, and the state S1c and the duty cycle of the state S1c is sent to the power controller PWRS1c.

Each power controller PWRS4c, PWRS3c, PWRS2c, and PWRS1c stores a respective one of the states S4c, S3c, S2c, and S1c and a respective one of the duty cycles of the states S4c, S3c, S2c, and S1c. For example, the processor of the power controller PWRS4c stores the state S4c and the duty cycle for which the state S4c is to occur in the memory device of the power controller PWRS4c, and the processor of the power controller PWRS3c stores the state S3c and the duty cycle for which the state S3c is to occur in the memory device of the power controller PWRS3c.

At the end of the time interval for the duty cycle of the state S1b and end of the first time period, the DSP 404 sends a power control signal to the power controller PWRS4c to provide the state S4c for the duty cycle of the state S4c. Upon receiving the power control signal, the power controller PWRS4c sends the state S4c to the driver system 406. The driver system 406 generates a drive signal upon receiving the state S4c and the frequency of operation based on the power level of the state S4c and the frequency of operation, and sends the drive signal to the RF power supply 408. The RF power supply 408 generates the RF signal 502 having the state S4c for the duty cycle of the state S4c and having the frequency of operation upon receiving the drive signal from the driver system 406.

The power controller PWRS4c determines that the time interval for the duty cycle of the state S4c has ended and stops sending the state S4c to the driver system 406 at the end of the duty cycle of the state S4c. When the driver system 406 does not receive the state S4c, the driver system 406 stops generating the drive signal based on the state S4c. Upon not receiving the drive signal based on the state S4c, the RF power supply 408 does not generate the state S4c of the RF signal 502.

At the end of the time interval for the duty cycle of the state S4c, the DSP 404 sends a power control signal to the power controller PWRS3c to provide the state S3c for the duty cycle of the state S3c. Upon receiving the power control signal, the power controller PWRS3c sends the state S3c to the driver system 406. The driver system 406 generates a drive signal upon receiving the state S3c and the frequency of operation based on the power level of the state S3c and the frequency of operation, and sends the drive signal to the RF power supply 408. The RF power supply 408 generates the RF signal 502 having the state S3c for the duty cycle of the state S3c and having the frequency of operation upon receiving the drive signal from the driver system 406.

Moreover, the power controller PWRS3c determines that the time interval for the duty cycle of the state S3c has ended and stops sending the state S3c to the driver system 406 at the end of the duty cycle of the state S3c. When the driver system 406 does not receive the state S3c, the driver system 406 stops generating the drive signal based on the state S3c. Upon not receiving the drive signal based on the state S3c, the RF power supply 408 does not generate the state S3c of the RF signal 502.

At the end of the time interval for the duty cycle of the state S3c, the DSP 404 sends a power control signal to the power controller PWRS2c to provide the state S2c for the duty cycle of the state S2c. Upon receiving the power control signal, the power controller PWRS2c sends the state S2c to the driver system 406. The driver system 406 generates a drive signal upon receiving the state S2c and the frequency of operation based on the power level of the state S2c and the frequency of operation, and sends the drive signal to the RF power supply 408. The RF power supply 408 generates the RF signal 502 having the state S2c for the duty cycle of the state S2c and having the frequency of operation upon receiving the drive signal from the driver system 406.

The power controller PWRS2c determines that the time interval for the duty cycle of the state S2c has ended and stops sending the state S2c to the driver system 406 at the end of the duty cycle of the state S2c. When the driver system 406 does not receive the state S2c, the driver system 406 stops generating the drive signal based on the state S2c. Upon not receiving the drive signal based on the state S2c, the RF power supply 408 does not generate the state S2c of the RF signal 502.

At the end of the time interval for the duty cycle of the state S2c, the DSP 404 sends a power control signal to the power controller PWRS1c to provide the state S1c for the duty cycle of the state S1c. Upon receiving the power control signal, the power controller PWRS1c sends the state S1c to the driver system 406. The driver system 406 generates a drive signal upon receiving the state S1c and the frequency of operation based on the power level of the state S1c and the frequency of operation, and sends the drive signal to the RF power supply 408. The RF power supply 408 generates the RF signal 502 having the state S1c for the duty cycle of the state S1c and having the frequency of operation upon receiving the drive signal from the driver system 406.

The power controller PWRS1c determines that the time interval for the duty cycle of the state S1c has ended and stops sending the state S1c to the driver system 406 at the end of the duty cycle of the state S1c. When the driver system 406 does not receive the state S1c, the driver system 406 stops generating the drive signal based on the state S1c. Upon not receiving the drive signal based on the state S1c, the RF power supply 408 does not generate the state S1c of the RF signal 502. In this manner, the DSP 404 controls the power controllers PWRS4c, PWRS3c, PWRS2c, and PWRS1c, and the frequency controller FC to generate the RF signal 502 having the states S4c, S3c, S2c, and S1c and the frequency of operation for the second time period.

In the embodiment in which the RF signal 130 (FIG. 1) is to initiate pulsing among the four states S4c through S1c at the time t0, the recipe signal 612 includes the indication to initiate pulsing the RF signal 502 among the states S4c through S1c instead of the indication to initiate the pulsing among the states S3b, S2b, and S1b. The DSP 404 stores, within the memory device of the DSP 404, the indication to initiate pulsing of the RF signal 130 among the states S4c through S1c. At the time to, the DSP 404 sends a power control signal to the power controller PWRS4c to provide the state S4c for the duty cycle of the state S4c.

In one embodiment, any of the functions, described herein, as being performed by the controllers PWRS3b, PWRS2b, PWRS1b, PWRS4c, PWRS3c, PWRS2c, PWRS1c and FC can be performed by the DSP 404.

In an embodiment, any of the functions, described herein, as being performed by one or more of the controllers PWRS3b, PWRS2b, PWRS1b, PWRS4c, PWRS3c, PWRS2c, PWRS1c and FC can be performed by a single controller or by two or more controllers.

It should be noted that in the embodiment in which the states S4c through S3c are to be applied after the states S3b through S1b, the LF RF generator is turned off during a sum of the first and second time periods, and is turned on after the sum of the first and second time periods.

Embodiments, described herein, may be practiced with various computer system configurations including hand-held hardware units, microprocessor systems, microprocessor-based or programmable consumer electronics, minicomputers, mainframe computers and the like. The embodiments, described herein, can also be practiced in distributed computing environments where tasks are performed by remote processing hardware units that are linked through a computer network.

In some embodiments, a controller is part of a system, which may be part of the above-described examples. The system includes semiconductor processing equipment, including a processing tool or tools, chamber or chambers, a platform or platforms for processing, and/or specific processing components (a wafer pedestal, a gas flow system, etc.). The system is integrated with electronics for controlling its operation before, during, and after processing of a semiconductor wafer or substrate. The electronics is referred to as the “controller,” which may control various components or subparts of the system. The controller, depending on processing requirements and/or a type of the system, is programmed to control any process disclosed herein, including a delivery of process gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks connected to or interfaced with the system.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, DSPs, chips defined as ASICs, PLDs, one or more microprocessors, or microcontrollers that execute program instructions (e.g., software). The program instructions are instructions communicated to the controller in the form of various individual settings (or program files), defining operational parameters for carrying out a process on or for a semiconductor wafer. The operational parameters are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

The controller, in some embodiments, is a part of or coupled to a computer that is integrated with, coupled to the system, otherwise networked to the system, or a combination thereof. For example, the controller is in a “cloud” or all or a part of a fab host computer system, which allows for remote access for wafer processing. The controller enables remote access to the system to monitor current progress of fabrication operations, examines a history of past fabrication operations, examines trends or performance metrics from a plurality of fabrication operations, to change parameters of current processing, to set processing steps to follow a current processing, or to start a new process.

In some embodiments, a remote computer (e.g. a server) provides process recipes to the system over a computer network, which includes a local network or the Internet. The remote computer includes a user interface that enables entry or programming of parameters and/or settings, which are then communicated to the system from the remote computer. In some examples, the controller receives instructions in the form of settings for processing a wafer. It should be understood that the settings are specific to a type of process to be performed on a wafer and a type of tool that the controller interfaces with or controls. Thus as described above, the controller is distributed, such as by including one or more discrete controllers that are networked together and working towards a common purpose, such as the fulfilling processes described herein. An example of a distributed controller for such purposes includes one or more integrated circuits on a chamber in communication with one or more integrated circuits located remotely (such as at a platform level or as part of a remote computer) that combine to control a process in a chamber.

Without limitation, in various embodiments, a plasma system, described herein, includes a plasma etch chamber, a deposition chamber, a spin-rinse chamber, a metal plating chamber, a clean chamber, a bevel edge etch chamber, a physical vapor deposition (PVD) chamber, a chemical vapor deposition (CVD) chamber, an atomic layer deposition (ALD) chamber, an atomic layer etch (ALE) chamber, an ion implantation chamber, a track chamber, or any other semiconductor processing chamber that is associated or used in fabrication and/or manufacturing of semiconductor wafers.

It is further noted that although the above-described operations are described with reference to a parallel plate plasma chamber, e.g., a capacitively coupled plasma chamber, etc., in some embodiments, the above-described operations apply to other types of plasma chambers, e.g., a plasma chamber including an inductively coupled plasma (ICP) reactor, a transformer coupled plasma (TCP) reactor, conductor tools, dielectric tools, a plasma chamber including an electron cyclotron resonance (ECR) reactor, etc. For example, an X MHz RF generator, a Y MHz RF generator, and a Z MHz RF generator are coupled to an inductor within the ICP plasma chamber.

As noted above, depending on a process operation to be performed by the tool, the controller communicates with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

With the above embodiments in mind, it should be understood that some of the embodiments employ various computer-implemented operations involving data stored in computer systems. These computer-implemented operations are those that manipulate physical quantities.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

In some embodiments, the operations, described herein, are performed by a computer selectively activated, or are configured by one or more computer programs stored in a computer memory, or are obtained over a computer network. When data is obtained over the computer network, the data may be processed by other computers on the computer network, e.g., a cloud of computing resources.

One or more embodiments, described herein, can also be fabricated as computer-readable code on a non-transitory computer-readable medium. The non-transitory computer-readable medium is any data storage hardware unit, e.g., a memory device, etc., that stores data, which is thereafter read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although some method operations, described above, were presented in a specific order, it should be understood that in various embodiments, other housekeeping operations are performed in between the method operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment described above are combined with one or more features of any other embodiment without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein, but may be modified within the scope and equivalents of the appended claims.

1. A method for reducing variability between features of a substrate, comprising:
generating, by a single radio frequency (RF) generator, a radio frequency (RF) signal; and
modifying the RF signal to transition among at least three states for a first time period.

2. The method of claim 1, wherein said modifying the RF signal to transition among the at least three states includes transitioning the RF signal in a step-down manner among the at least three states, wherein said transitioning the RF signal in the step-down manner includes:
transitioning the RF signal from a first power level to a second power level, wherein the first power level is greater than the second power level;
transitioning the second power level to a third power level of the RF signal, wherein the third power level is less than the second power level.

3. The method of claim 1, wherein the RF signal is modified for transitioning the RF signal among the at least three states to etch a dielectric layer of the substrate.

4. The method of claim 1, wherein the RF signal is modified for transitioning the RF signal among the at least three states to etch a mask layer and a first portion of a dielectric layer of the substrate, wherein the at least at least three states of the RF signal etch a second portion of the dielectric layer, wherein the second portion is located below the first portion.

5. The method of claim 4, further comprising modifying the RF signal to transition to four states for a second time period after the first time period or modifying the RF signal to increase a power level of one of the at least three states, wherein the four states of the RF signal etch a third portion of the dielectric layer, wherein the third portion is located below the second portion.

6. The method of claim 1, wherein the RF signal is generated to have at least one state to etch a first portion of a dielectric layer of the substrate, wherein the RF signal is modified for transitioning the RF signal among the at least three states to etch a second portion of the dielectric layer, wherein the second portion is located below the first portion.

7. The method of claim 1, further comprising supplying the RF signal to an impedance matching circuit, wherein during said supplying the RF signal to the impedance matching circuit, another RF signal is not supplied to the impedance matching circuit.

8. The method of claim 1, wherein the single RF generator has a single frequency of operation, wherein the single frequency is a fundamental frequency of 60 megahertz (MHz).

9. The method of claim 1, wherein the at least three states includes at most four states.

10. A controller for reducing variability between features of a substrate, comprising:
a processor configured to control a single radio frequency (RF) generator to generate an RF signal,
wherein the processor is configured to further control the RF generator to transition the RF signal to among at least three states for a first time period; and
a memory device coupled to the processor.

11. The controller of claim 10, wherein to control the single RF generator to transition the RF signal among the at least three states, the processor is configured to control the single RF generator to transition the RF signal in a step-down manner among the at least three states, wherein to transition the RF signal in the step-down manner, the processor is configured to:
control the single RF generator to transition the RF signal from a first power level to a second power level, wherein the first power level is greater than the second power level;
control the single RF generator to transition the second power level to a third power level of the RF signal, wherein the third power level is less than the second power level.

12. The controller of claim 10 wherein the RF signal is controlled for transitioning the RF signal among the at least three states to etch a dielectric layer of the substrate.

13. The controller of claim 10, wherein the RF signal is controlled to transition the RF signal among the at least three states to etch a mask layer and a portion of a first dielectric layer of the substrate, wherein the at least three states of the RF signal etch a second portion of the dielectric layer, wherein the second portion is located below the first portion.

14. The controller of claim 13, wherein the processor is configured to modify the RF signal to transition to four states for a second time period after the first time period or modify the RF signal to increase a power level of one of the at least three states, wherein the four states of the RF signal etch a third portion of the dielectric layer, wherein the third portion is located below the second portion.

15. The controller of claim 10, wherein the RF signal is generated to have at least one state to etch a first portion of a dielectric layer of the substrate, wherein the RF signal is modified for transitioning the RF signal among the at least three states to etch a second portion of the dielectric layer, wherein the second portion is located below the first portion.

16. The controller of claim 10, wherein the RF signal is supplied to an impedance matching circuit, wherein during a time period in which the RF signal is supplied to the impedance matching circuit, another RF signal is not supplied to the impedance matching circuit.

17. The controller of claim 10, wherein the single RF generator has a single frequency of operation, wherein the single frequency is a fundamental frequency of 60 megahertz (MHz).

18. The controller of claim 10, wherein the at least three states includes at most four states.

19. A plasma system comprising:
a single radio frequency (RF) generator configured to generate an RF signal;
a match coupled to the single RF generator;
a plasma chamber coupled to the match; and
a controller coupled to the single RF generator, wherein the controller is configured to:
control the single RF generator to generate the RF signal; and
control the single RF generator to transition the RF signal among at least three states for a first time period.

20. The plasma system of claim 19, wherein to control the single RF generator to transition the RF signal among the at least three states, the controller is configured to control the single RF generator to transition the RF signal in a step-down manner among the at least three states, wherein to transition the RF signal in the step-down manner, the controller is configured to:
control the single RF generator to transition the RF signal from a first power level to a second power level, wherein the first power level is greater than the second power level;
control the single RF generator to transition the second power level to a third power level of the RF signal, wherein the third power level is less than the second power level.

21. The plasma system of claim 19, wherein the controller is configured to modify the RF signal to transition to four states for a second time period after the first time period or modify the RF signal to increase a power level of one of the at least three states.

22. The plasma system of claim 19, wherein the single frequency is a fundamental frequency of 60 megahertz (MHz), and the at least three states includes at most four states.
